(19) United States
(12) Patent Application Publication
(10) Pub. No.: US 2010/0259184 A1
(43) Pub. Date: Oct. 14, 2010

(54) LIGHT-EMITTING DEVICE

(76) Inventors: Ryou Kato, Hyogo (JP); Yasutoshi Kawaguchi, Hyogo (JP); Akihiko Ishibashi, Osaka (JP); Toshiya Yokogawa, Nara (JP)

Correspondence Address: MARK D. SARALINO (PAN);RENNER, OTTO, BOISSELLE & SKLAR, LLP, 1621 EUCLID AVENUE, 19TH FLOOR, CLEVELAND, OH, 44115, US

(21) Appl. No.: 12/279,573

(22) PCT Filed: Feb. 15, 2007
(86) PCT No.: PCT/JP2007/052717

§ 371 Date: Aug. 15, 2008

(30) Foreign Application Priority Data
Feb. 24, 2006 (JP) 2006-048903

(51) Int. Cl. H01L 33/44; H01L 27/15; H01L 33/02; H05B 37/02

(52) U.S. Cl. 315/291; 257/98; 257/91; 257/E33.005; 257/E27.121; 257/E33.061

(57) ABSTRACT

A light-emitting device according to the present invention includes a plurality of columnar semiconductors 30 arranged on a GaN substrate 7, and a plurality of protrusions 13 formed on a side face of each columnar semiconductor 30. Each columnar semiconductor 30 has a light-emitting portion composed of a nitride compound semiconductor, and is supported by the GaN substrate 7 at a lower end. The columnar semiconductor 30 has a multilayer structure including an n-cladding layer 9, an active layer 10, and a p-cladding layer 11, the active layer 10 having a multi-quantum well structure in which In_{W}Ga_{1-W}N (0<W<1) well layers and GaN barrier layers are alternately deposited.

### TECHNICAL FIELD

The present invention relates to a light-emitting device.

### BACKGROUND ART

Light-emitting devices of wavelengths in the blue to ultraviolet region are drawing attention as light sources for optical disks that are capable of high-density recording, and as an element technology for full-color displays. In order to realize a white LED light source having excellent color rendition, studies on simultaneously exciting a plurality of types of phosphor by using ultraviolet LEDs of wavelengths of 400 nm or less are being vigorously made.

In an LED which emits light of a wavelength in the blue to ultraviolet region, a gallium nitride (GaN) type compound semiconductor (In_{W}Ga_{1-W}N, 0<W<1) containing indium is often used for its active layer. In an LED in which a GaN-type compound semiconductor is used, it is necessary to reduce the indium content in the active layer in the case where the emission wavelength short is short. However, reducing the indium content will eliminate the localization of carriers caused by segregation of indium, so that the threading dislocations which have always existed in the active layer will have an increased influence as non-radiative centers, thus deteriorating the emission efficiency of the LED. Generally speaking, in an ultraviolet LED, there is a tendency that the emission efficiency is greatly deteriorated when the wavelength of the emitted light becomes approximately 400 nm or less.

In order to obtain an improved emission efficiency, attempts to reduce the threading dislocation density are being actively made. Non-Patent Documents 1 and 2 disclose a technique of forming nanoscale columnar structures in order to greatly reduce threading dislocations which are likely to occur in thin film structures and obtain improved emission characteristics.

FIG. 10 schematically shows a structure which is disclosed in Non-Patent Document 1. The structure of FIG. 10 is a columnar LED (nanocolumn LED) supported by an n-Si substrate 1, and has a structure in which an n-GaN cladding layer 2, an un-GaN layer 3, an InGaN/GaN multi-quantum well layer 4, an un-GaN layer 5, and a p-GaN cladding layer 6 are stacked in this order, beginning from the substrate 1. When a voltage is applied between the Si substrate 1 and the p-GaN cladding layer 6, light is emitted from a light-emitting portion which is interposed between the cladding layers 2 and 6. As used herein, cladding layers are layers sandwiching a light-emitting portion and being composed of a substance which has a larger band gap and a smaller refractive index than those of the light-emitting portion, the cladding layers serving to confine light and carriers in the light-emitting portion.

In recent years, it has been proposed to utilize self-organization of crystals as a method of forming a semiconductor having a columnar structure. Non-Patent Document 3 discloses growing numerous offshoot crystals on the side faces of a columnar structure by using zinc oxide (ZnO), the columnar structure serving as an axis. In such a structure, the offshoot portions are allowed to function as resonators, thus performing induced emission.

By the way, in order to improve the emission efficiency, various attempts are being made not only to improve the crystallinity of the device, but also to improve the light extraction efficiency mainly from within the interior of the device.

When producing an LED from a GaN-type compound semiconductor, it is preferable to use a GaN substrate in order to suppress, as much as possible, the occurrence of threading dislocations serving as non-radiative centers. However, when the emission wavelength is 370 nm or less, i.e., near the band gap of GaN, the light emitted from the light-emitting portion is absorbed by the GaN substrate, so that the emission efficiency is significantly lowered. In order to solve such a problem, Patent Document 1 discloses a method in which a GaN substrate that was used for the formation of an LED structure is peeled after the LED structure is produced. In accordance with the LED which is produced by this method, an external quantum efficiency of 26% is realized by light emission in the ultraviolet region during DC driving (current: 1 A).

When light is emitted from the interior of the light-emitting device to the outside, reflection may occur at a boundary plane due to a difference in refractive index between media, this being one cause that lowers the light extraction efficiency of the light-emitting device. In order to solve this problem, Patent Document 2 discloses providing protrusions and depressions on the light-emitting surface of an LED, which is conventionally flat, and allowing the direction of travel of light which is emitted by the light-emitting portion to be turned with these protrusions and depressions, thus increasing the amount of light going out of the light-emitting device.

[Patent Document 1] Japanese Laid-Open Patent Publication No. 2005-93988

[Patent Document 2] Japanese Laid-Open Patent Publication No. 2005-64113

[Non-Patent Document 1] Japanese Journal of Applied Physics, Vol. 43, No. 12A, 2004, L1524.

[Non-Patent Document 2] Nano Letters, Vol. 4, No. 6, 2004, 1059.

[Non-Patent Document 3] Applied Physics Letters, Vol. 86, 2005, 011118.

### DISCLOSURE OF INVENTION

### Problems to be Solved by the Invention

Many of the conventional thin-film type nitride compound semiconductor light-emitting devices do not allow for sufficient reduction in dislocation density within the crystal, despite various measures being taken. This makes it impossible to achieve an emission efficiency high enough to realize a practical light-emitting device for solid-state lighting. Therefore, light-emitting devices are under study which have columnar structures in order to reduce threading dislocations, but they have a problem in that the light extraction efficiency from the interior of the light-emitting device to the outside is not sufficiently high.

The techniques that have so far been disclosed for forming protrusions and depressions on the light-emitting surface for improving the light extraction efficiency of a light-emitting device involve a problem in that the production steps of the device are greatly complicated. Since there is also a problem in that the emitted light is absorbed by the GaN substrate at wavelengths in the ultraviolet region of 370 nm or less, a step of peeling the GaN substrate may become necessary, for example, thus also complicating the production steps of the device.

The present invention has been made in order to solve the aforementioned problems, and an objective thereof is to provide a light-emitting device which has a low threading dislocation density and an excellent crystallinity, and which permits a very easy production for attaining an improved light extraction efficiency.

### Means for Solving the Problems

A light-emitting device according to the present invention comprises: at least one columnar semiconductor having a light-emitting portion composed of a nitride compound semiconductor; a plurality of protrusions formed on a side face of the columnar semiconductor; and a p electrode and an n electrode for supplying a current to the light-emitting portion.

In a preferred embodiment, an interface at which each of the plurality of protrusions is in contact with the columnar semiconductor has an area of no less than 1×10² nm² and no more than 5×10⁵ nm².

In a preferred embodiment, each of the plurality of protrusions has a size of no less than 5 nm and no more than 500 nm along a direction perpendicular to an axial direction of the columnar semiconductor.

In a preferred embodiment, the plurality of protrusions are distributed on the side face of the columnar semiconductor at an interval of no less than 10 nm and no more than 1000 nm from one another.

In a preferred embodiment, each of the plurality of protrusions has a column, a cone, a dome, or a combined shape thereof, or any like shape.

In a preferred embodiment, each of the plurality of protrusions is composed of a material different from a material of the columnar semiconductor.

In a preferred embodiment, each of the plurality of protrusions is composed of a material having a larger band gap than a band gap of the nitride semiconductor in the light-emitting portion.

In a preferred embodiment, the protrusions are composed of a material which does not absorb light generated in the light-emitting portion.

In a preferred embodiment, the columnar semiconductor has a multilayer structure including an n-cladding layer, a p-cladding layer, and an active layer provided between the n-cladding layer and the p-cladding layer, the active layer functioning as the light-emitting portion.

In a preferred embodiment, a plurality of said columnar semiconductors are comprised, and a substrate supporting the plurality of columnar semiconductors is comprised.

In a preferred embodiment, the substrate is composed of a nitride compound semiconductor.

In a preferred embodiment, a phosphor material is provided in between the plurality of columnar semiconductors.

In a preferred embodiment, the phosphor material absorbs at least a portion of light which is emitted from the columnar semiconductor, contains a phosphor which emits light having a longer wavelength than a wavelength of the light, and is filled in between the columnar semiconductors.

In a preferred embodiment, one of the p electrode and the n electrode covers the plurality of columnar semiconductors and the phosphor material.

In a preferred embodiment, at least one first conductive layer connected to the p electrodes of the plurality of columnar semiconductors, and at least one second conductive layer connected to the n electrodes of the plurality of columnar semiconductors are comprised.

In a preferred embodiment, the first conductive layer and the second conductive layer serve also as, respectively, a plurality of p electrodes and a plurality of n electrodes.

In a preferred embodiment, the phosphor material is located between a plane which is defined by the first conductive layer and a plane which is defined by the second conductive layer.

In a preferred embodiment, a cross section of each of the plurality of columnar semiconductors taken along a plane which is perpendicular to an axial direction thereof has an area of no less than 1×10³ nm² and no more than 1×10⁶ nm².

In a preferred embodiment, a cross section of the columnar semiconductor taken along a plane perpendicular to an axial direction is a polygon or a circle.

In a preferred embodiment, each of the plurality of columnar semiconductors has a length of no less than 1×10² nm and no more than 1×10⁵ nm along an axial direction.

A light-emitting device according to the present invention comprises: a substrate; a plurality of columnar semiconductors arranged on the substrate, each having a light-emitting portion composed of a nitride compound semiconductor; a plurality of protrusions formed on a side face of each columnar semiconductor; a phosphor material being filled in between the plurality of columnar semiconductors and being in contact with the columnar semiconductors; a first electrode layer covering the phosphor material and the plurality of columnar semiconductors and being electrically connected to one end of each columnar semiconductor; and a second electrode layer being electrically connected to another end of each columnar semiconductor.

An illumination device according to the present invention comprises: any of the aforementioned light-emitting devices; and a circuit for controlling emission of light by the light-emitting device.

### EFFECTS OF THE INVENTION

In a light-emitting device according to the present invention, a columnar semiconductor(s) performs light emission, so that density of defects can be reduced as compared to the case where semiconductor layers are grown on a substrate in laminar forms. Moreover, since protrusions are present on a side face of the columnar semiconductor(s), light which is generated in the light-emitting portion can be efficiently taken outside via the protrusions. Such protrusions do not have the long dendriform structure disclosed in Non-Patent Document 3, and no contact occurs between adjoining protrusions, and therefore light can be efficiently emitted outside. Furthermore, the plurality of protrusions on the side face of the columnar semiconductor(s) can be very easily formed, and thus complication of the production steps of the device for the purpose of improving the light extraction efficiency, which cannot be avoided by conventional techniques, can be eliminated.

### BRIEF DESCRIPTION OF DRAWINGS

FIG. 1 A vertical cross-sectional view schematically showing the construction of a light-emitting device according to Embodiment 1 of the present invention.

FIG. 2 A vertical cross-sectional view of a columnar semiconductor according to Embodiment 1.

FIG. 3 A diagram showing a planar layout of a mask layer according to Embodiment 1.

FIG. 4 A horizontal cross-sectional view of a columnar semiconductor according to Embodiment 1.

FIG. 5 An upper plan view of a light-emitting device according to Embodiment 1 before a p electrode is formed.

FIG. 6 A schematic cross-sectional view showing a variant of Embodiment 1.

FIG. 7 (a) is a diagram schematically showing a path of light which is emitted from an active layer according to a Comparative Example; and (b) is a diagram schematically showing a path of light which is emitted from an active layer of a columnar semiconductor according to an Embodiment of the present invention.

FIG. 8 A graph showing light extraction efficiency concerning an Example and a Comparative Example.

FIG. 9 A vertical cross-sectional view schematically showing the construction of light-emitting device according to Embodiment 2 of the present invention.

FIG. 10 A diagram schematically showing a cross-sectional structure of a columnar semiconductor which is produced by a method described in Non-Patent Document 1.

FIG. 11 A graph showing light extraction efficiency concerning an Example.

FIG. 12 A graph showing light extraction efficiency concerning an Example.

### DESCRIPTION OF THE REFERENCE NUMERALS

1 substrate
2 n-GaN
3 un-GaN
4 InGaN/GaN multi-quantum well
5 un-GaN
6 p-GaN
7 GaN substrate
8 mask layer
9 n-GaN cladding layer
10 In_{W}Ga_{1-W}N (0<W<1)/GaN active layer
11 p-GaN cladding layer
12 p-GaN contact layer
13 AlN protrusions
14 mask aperture
15 phosphor material
16 p electrode
17 n electrode
18 n-Al_{X}Ga_{1-X}N (0≦X≦1) buffer layer
19 n-Al_{Y}Ga_{1-Y}N (0≦Y≦1) cladding layer
20 p-Al_{Z}Ga_{1-Z}N (0≦Z≦1) cladding layer
21 AlN protrusions
30 columnar semiconductor
40 columnar semiconductor

### BEST MODE FOR CARRYING OUT THE INVENTION

### Embodiment 1

A first embodiment of a light-emitting device according to the present invention will be described.

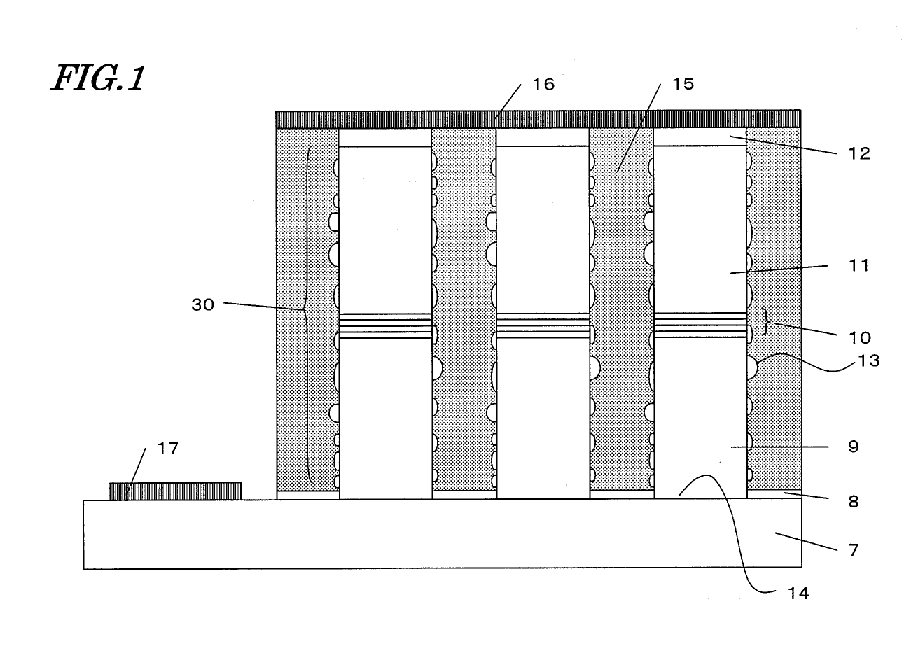

As shown in FIG. 1, the light-emitting device of the present embodiment includes a plurality of columnar semiconductors 30 arranged on a GaN substrate 7, and a plurality of protrusions 13 formed on side faces of each columnar semiconductor 30. Although FIG. 1 illustrates three columnar semiconductors 30, a multitude of columnar semiconductors are arranged on the GaN substrate in actuality.

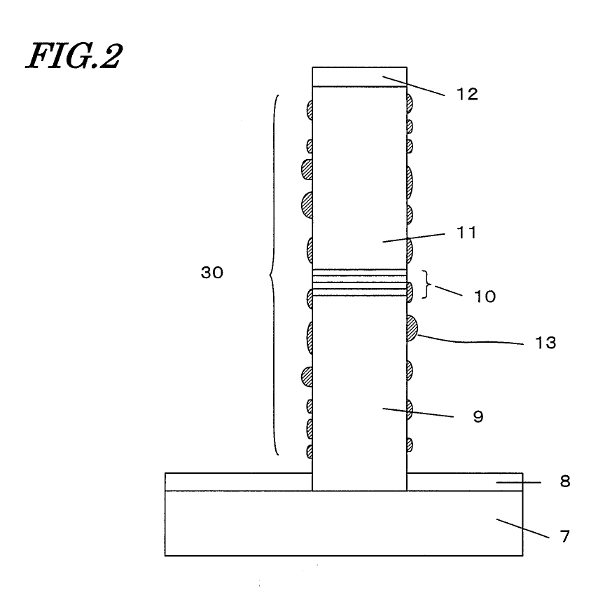

As shown in FIG. 2, each columnar semiconductor 30 includes a light-emitting portion composed of a nitride compound semiconductor, with its lower end being supported by the GaN substrate 7. The columnar semiconductor 30 has a multilayer structure including an n-cladding layer 9, an active layer 10, and a p-cladding layer 11. The active layer has a multi-quantum well structure in which In_{W}Ga_{1-W}N (0<W<1) well layers and GaN barrier layers are alternately deposited, thus functioning as the light-emitting portion. The n-cladding layer 9 and the p-cladding layer 11 may be composed of a substance which has a larger band gap and a smaller refractive index than those of the substance composing the active layer 10, which would appropriately be AlₛGa₁₋ₛN (0≦s≦1) or the like in the case where the active layer 10 is constructed from 1n_{W}Ga_{1-W}N (0<W<1) well layers and GaN barrier layers. Thus, each columnar semiconductor 30 in the present embodiment functions as an LED (Light Emitting Diode).

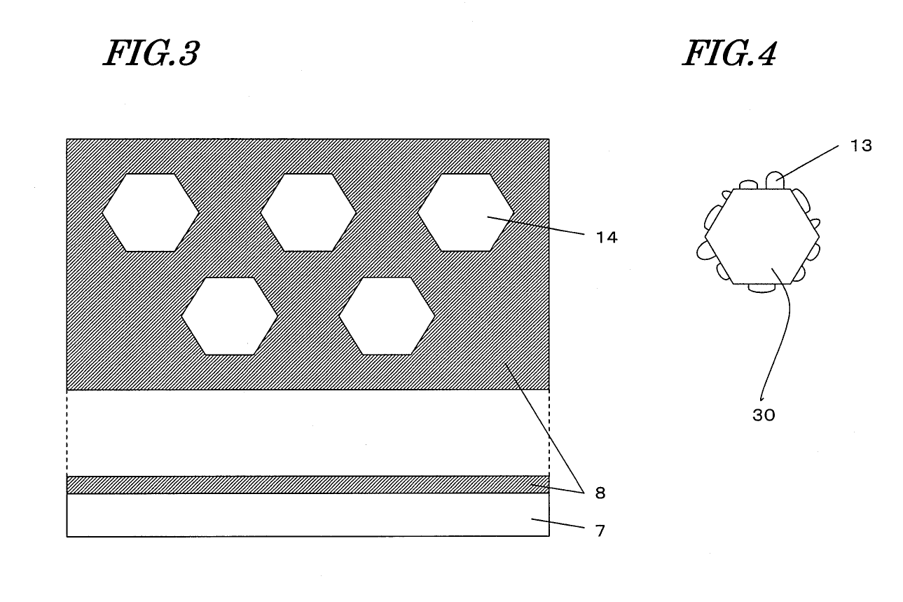

The principal face of the GaN substrate 7 is covered by a mask layer 8 shown in FIG. 3. The mask layer 8 is composed of an insulator such as tantalum oxide (Ta₂O₅), and may be any that functions as a selective growth mask against the crystal growth of the columnar semiconductors 30. In the mask layer 8, a plurality of hexagonal apertures 14 defining regions in which the columnar semiconductors 30 are to be selectively grown are formed. The lower ends of the columnar semiconductors 30 are in contact with a principal face of the GaN substrate 7 via the apertures 14.

Each columnar semiconductor 30 in the present embodiment is composed of a nitride semiconductor material, and has a complete wurtzite structure. Therefore, the longitudinal direction (growth direction) of each columnar semiconductor 30 substantially coincides with the c axis direction of a nitride semiconductor crystal, and the columnar semiconductor 30 has a hexagonal column shape having 6-fold symmetry with respect to its center axis. For this reason, the shape of each aperture 14 in the mask layer 8 used in the present embodiment is a hexagon; however, it may be any other polygon, or a circle.

The protrusions 13 present on the side faces of the columnar semiconductor 30 are composed of a material which does not absorb light that is generated in the active layer 10. In other words, the protrusions 13 are composed of a material which has a larger band gap than the band gap of the active layer 10. Specifically, the light generated in the active layer 10 has a wavelength of about 250 to 500 nm, and the protrusions 13 are composed of a material which does not absorb this light (which is An in the present embodiment). Other than AlN, GaN, diamond, BN (boron nitride) or the like may also be used as a material of the protrusions 13.

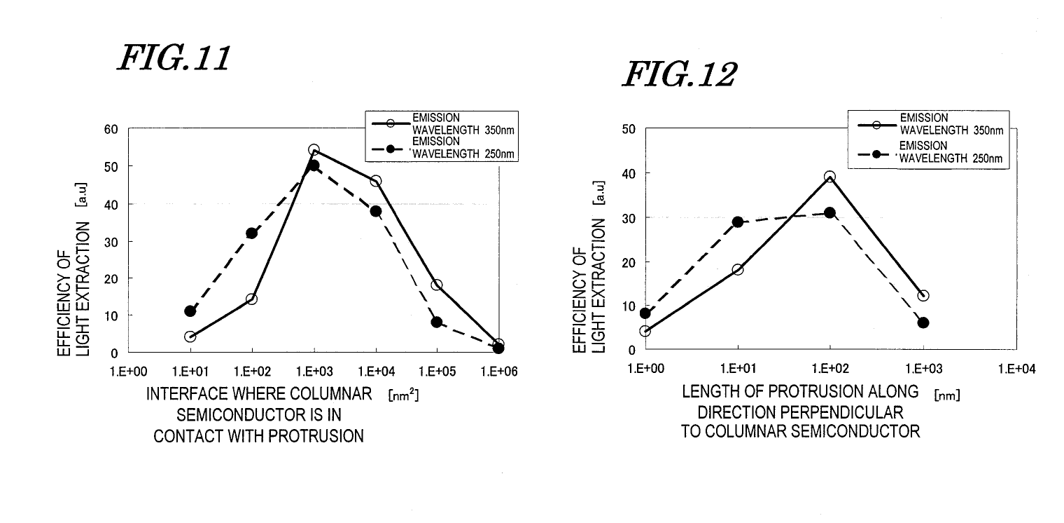

FIG. 11 shows results of calculating, through a simulation, a relationship between the area of an interface where an AlN protrusion 13 is in contact with the columnar semiconductor 30 and the light extraction efficiency of the device. FIG. 12 shows results of calculating, through a simulation, a relationship between the size of an AlN protrusion 13 along a direction that is perpendicular to the axial direction of the columnar semiconductor 30 and the light extraction efficiency of the device. When the protrusion 13 becomes too large, the proportion of light which undergoes total reflection in the interior of the device increases. Conversely, when the protrusion 13 becomes too small, light is not propagated into the interior of the protrusion 13. In other words, in order to increase the light extraction efficiency of the device, there exists an optimum range for the area of the interface where the protrusion 13 is in contact with the columnar semiconductor 30, which is approximately no less than 1×10² nm² and no more than 5×10⁵ nm². Similarly, in order to increase the light extraction efficiency of the device, there exists an optimum range for the size of the AlN protrusion 13 along a direction that is perpendicular to the axial direction of the columnar semiconductor 30, which is approximately no less than 5 nm and no more than 500 nm. Moreover, a good light extraction efficiency is obtained when each AlN protrusion 13 has a column, a cone, a dome, or a combined shape thereof, or any like shape.

FIG. 1 is again referred to.

In the light-emitting device of the present embodiment, a phosphor material 15 is filled in between the plurality of columnar semiconductors 30. FIG. 5 shows a schematic cross-sectional view of the light-emitting device of the present embodiment as seen from above. The phosphor material 15 contains phosphor such as the Y₃Al₅O₁₂:Ce type, for example. The characteristics of the phosphor material 15 are such that it efficiently absorbs light which is generated in the active layer 10 and emits light of a longer wavelength (wavelength: e.g. 500 to 780 nm). The light which is emitted from the phosphor material 15 (e.g. yellow light) is mixed with the light which is directly emitted from the active layers 10 of the columnar semiconductors 30 (violet to blue light), whereby intermixing of colors occurs. In this manner, when the type of phosphor is appropriately selected, light which is close to white light as a whole is obtained, thus rendering the light-emitting device of the present embodiment suitable for use as an illumination device. In the case where the light generated by the active layer 10 has a short wavelength and therefore is not visible light, visible light can be obtained since the phosphor is excited by such short-wavelength light.

In order to cause light emission in the active layer 10, it is necessary to create an electric field along the vertical direction in the interior of the columnar semiconductor 30, thus generating a current through the active layer 10. Therefore, in the present embodiment, a common p electrode 16 is provided which is in electrical contact with the p-GaN contact layers 12 of all of the columnar semiconductors 30. On the other hand, an n electrode 17 is provided in a portion of the principal face of the GaN substrate 7 where the columnar semiconductor 30 do not exist, and is electrically connected to the lower end of each columnar semiconductor 30 via the GaN substrate 7. When a voltage of an appropriate magnitude is applied between the p electrode 16 and the n electrode 17 with an external circuit not shown, holes flow into the active layer 10 of each columnar semiconductor 30 from the p electrode 16, and electrons flow into the active layer of each columnar semiconductor 30 from the n electrode 17 via the GaN substrate 7. Recombination of holes and electrons occurs in the active layer 10, whereby light is emitted.

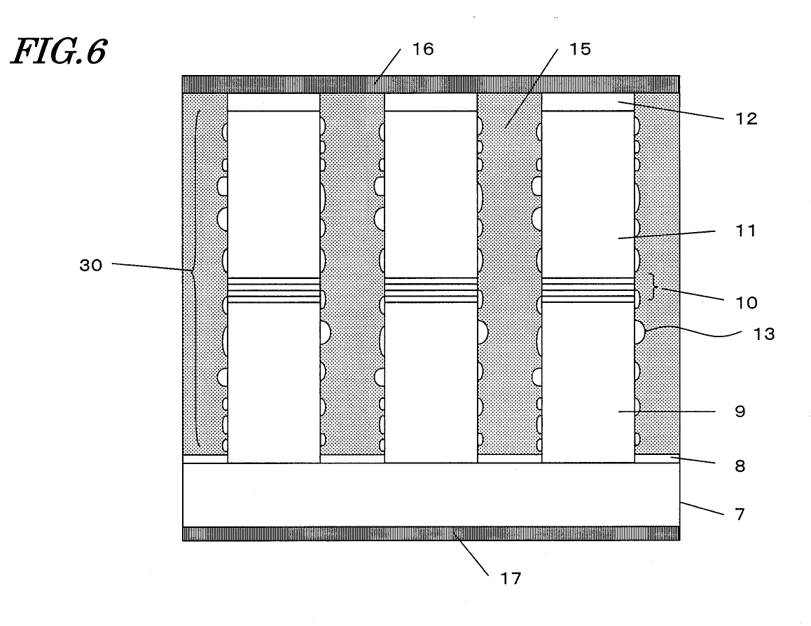

Note that, as shown in FIG. 6, an n electrode 17 may be formed on the rear face side of the GaN substrate 7. Other than the GaN substrate 7, any substrate that is electrically conductive, e.g. SiC, will allow the n electrode 17 to be formed on the rear face of the substrate.

A p electrode 16 may be individually formed on the upper face of each columnar semiconductor 30, and/or connected via a wiring layer or the like which is not shown. Also, the n electrode 17 may be connected to a wiring layer that interconnects the columnar semiconductors 30.

As has been described with reference to FIG. 3, a columnar semiconductor 30 grows from a region of the principal face of the GaN substrate 7 where an aperture 14 in the mask layer 8 exists. Although threading dislocations exist in the GaN substrate 7, the portion of any threading dislocation that reaches the principal face of the GaN substrate 7 is mostly covered with the mask layer 8. By adjusting the ratio of the area of the aperture 14 with respect to the area of the masking portion of the mask layer 8, the probability of the threading dislocations reaching the positions of the apertures 14 can be made very small.

Generally speaking, threading dislocations exist at a density of about 1×10⁶ to 1×10⁸ cm⁻² in the GaN substrate 7. Therefore, by setting the area of the aperture 14 to about 1×10⁶ nm² or less, it can be ensured that the average number of threading dislocations that may be contained in the region defined by each aperture 14 is one or less. By doing so, the risk of the crystallinity of each columnar semiconductor 30 being deteriorated by the threading dislocations can be greatly reduced. Thus, the size of the aperture 14 will define the area of a cross section of the columnar semiconductor 30 that is taken along a plane which is perpendicular to the axial direction. In many cases, this cross section is a polygon, preferably having an area of 1×10⁶ nm² or less. When the cross-sectional area is smaller than 1×10³ nm², it becomes difficult to form the protrusions 13 on the side faces of the columnar semiconductor 30.

Desirably, the length of each columnar semiconductor 30 along the axial direction is 1×10⁵ nm or less because, if the ratio obtained by dividing the length along the axial direction by the width of the cross section exceeds approximately 100, the proportion of those which may fall due to external stress will increase. On the other hand, in order to form the protrusions 13 on the side faces of the columnar semiconductor 30, the length along the axial direction must at least be about 1×10² nm.

According to the light-emitting device of the present embodiment, not only that the threading dislocations running through the active layer 10 are reduced, there is also obtained an effect of increasing the surface area of the light-emitting portion because of the presence of the AlN protrusions 13. Moreover, due to the multitude of crystal planes present on the AlN protrusions 13, reflection of emitted light is effectively suppressed at the boundaries between the light-emitting device and the outside. Due to such effects associated with the AlN protrusions 13, the light extraction efficiency from the light-emitting device is improved.

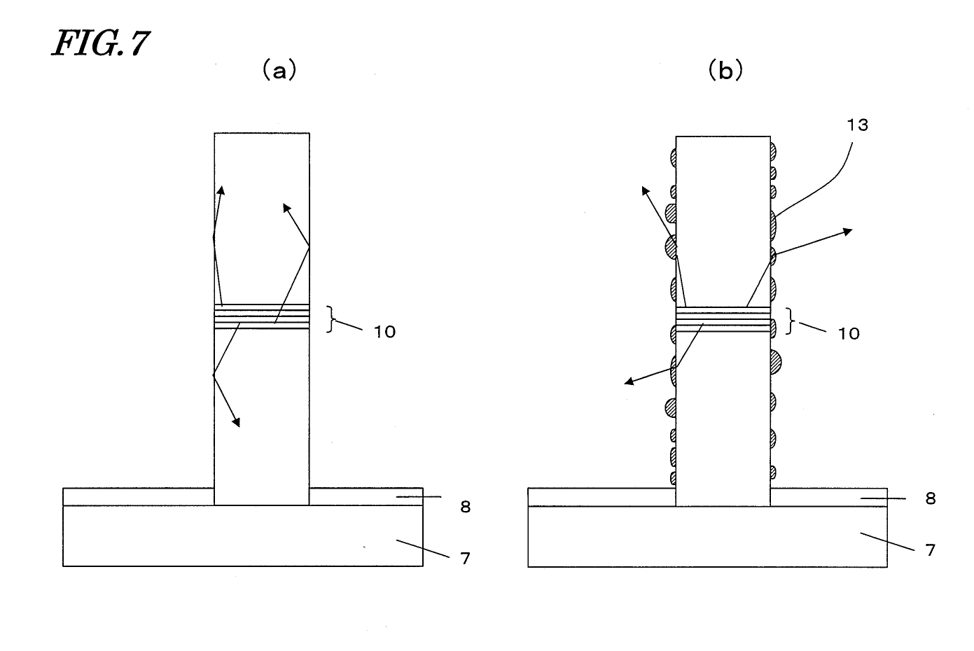

FIG. 7(a) shows a columnar semiconductor having no AlN protrusions 13 formed on the side faces, and FIG. 7(b) shows a columnar semiconductor according to the present embodiment. Arrows in the figure schematically show a path of light generated in the active layer 10. As can be seen from FIG. 7(a), in the case where no AlN protrusions 13 exist on the side faces of the columnar semiconductor, total reflection is likely to occur on the inside of the smooth side faces, so that light is unlikely to go outside of the columnar semiconductor. On the other hand, as can be seen from FIG. 7(b), presence of the AlN protrusions 13 make total reflection unlikely to occur, so that the proportion of light going outside of the columnar semiconductor increases consequently.

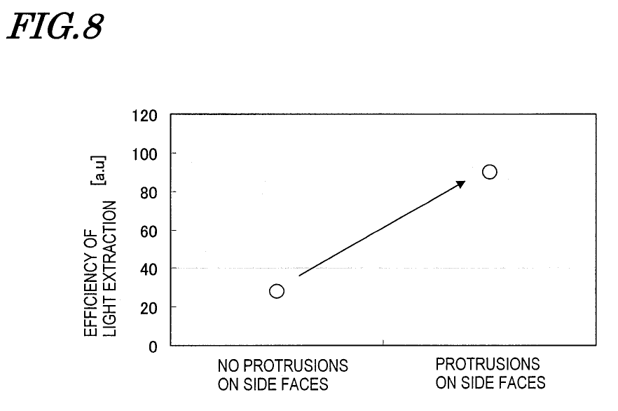

FIG. 8 shows results of a simulation by the inventors. Assuming that a hexagonal columnar semiconductor whose cross section has an area of 1×10⁵ nm² undergoes a light emission at a wavelength of 380 nm, a comparison in emission efficiency is made between: a columnar semiconductor having conical protrusions in a uniform arrangement on its side faces, the size of each conical protrusions along a direction perpendicular to the axial direction of the columnar semiconductor being 40 nm and its contact area with the columnar semiconductor being 1.5×10⁴ nm²; and a columnar semiconductor having no structures on its side faces. This comparison shows that the light extraction effect of the columnar semiconductor having protrusions on its side faces is approximately three times as high. Note that the shape of the protrusions is not limited to a cone, and it is considered that a similar effect will be obtained also with a column or dome shape.

Moreover, in the present embodiment, the space between the columnar semiconductors 30 is filled with the phosphor material 15, so that most of the light which is emitted from the active layer 10 can efficiently excite the phosphor. By taking into consideration the fact that light will simultaneously exit from the GaN protrusions 13 that are present on all columnar semiconductors 30, the emitted light will travel in various directions and impartially excite the surrounding phosphor material 15.

Furthermore, the fact that the phosphor material 15 fills between the columnar semiconductors 30 also provides an effect of preventing the columnar semiconductors 30 from falling and facilitating the formation of a p electrode 16 that is common to the columnar semiconductors 30.

Next, a preferable embodiment of producing the light-emitting device of the present embodiment will be described. The light-emitting device of the present embodiment is formed via crystal growth using metal-organic vapor phase epitaxy (MOVPE) technique.

First, the GaN substrate 7 on which to grow the columnar semiconductor 30 is provided, and the mask layer 8 is formed on the GaN substrate 7. The mask layer 8 can be easily produced by depositing a film composed of a material that functions as a selective growth mask on a principal face of the GaN substrate 7, and thereafter patterning the film by photolithography and etching technique. The planar pattern of the mask layer 8 is not limited to that which is shown in FIG. 3.

Although the shape and arrangement of the apertures 14 in the mask layer 8 may be arbitrary, it is preferable that they have a near-hexagonal shape by taking into consideration the crystallinity of GaN as mentioned above. Note that, in the case where the shape of each aperture 14 in the mask layer 8 is prescribed to be a circle or a polygon such as a triangle, it also becomes possible through adjustments of the growth conditions to grow a columnar semiconductor having a cross-sectional shape which is defined by the shape of the aperture 14.

Moreover, by setting the size and number per unit area of the apertures 14 while taking into consideration the threading dislocations in the GaN substrate 7, it becomes possible to greatly reduce the number of threading dislocations that reach each columnar semiconductor 30.

Next, the GaN substrate 7 having the mask layer 8 formed on its principal face is placed on a susceptor which is in the reactor of an MOVPE apparatus, with its (0001) plane facing up as an upper face. After the interior of the reactor is evacuated, the susceptor is heated to a high temperature so as to effect a cleaning for the surface of the GaN substrate 7.

Next, the temperature of the susceptor is adjusted to 900 to 1000° C., and an appropriate amount of each of trimethylgallium (TMG), ammonia (NH₃), and monosilane (SiH₄) is supplied into the reactor, together with a hydrogen carrier gas. Thus, the n-GaN cladding layer 9, which is doped with an n-type impurity, is selectively grown only on the portions of the mask layer 8 where the apertures 14 exist. The cross section of each semiconductor which is grown on the n-GaN cladding layer 9 is defined by the shape of the apertures 14 in the mask layer 8.

Next, supply of SiH₄ is stopped, and the susceptor is cooled to near 800° C. After the carrier gas is switched from hydrogen to nitrogen, TMG and newly trimethylindium (TMI) are supplied, whereby In_{W}Ga_{1-W}N (0<W<1) well layers are formed. Then, supply of TMI is stopped, whereby GaN barrier layers are formed. By alternately depositing these layers, the active layer 10 composed of a multi-quantum well can be formed. By controlling the supply amount of TMI, well layer thickness, barrier layer thickness, and the like, the wavelength of the light which is emitted from the active layer 10 can be adjusted.

Next, the carrier gas is again switched to hydrogen, the temperature of the susceptor is elevated to about 900 to 1000° C., and bis(cyclopentadienyl)magnesium (Cp₂Mg) is supplied, thus depositing the p-GaN cladding layer 11, which is doped with a p-type impurity.

After the p-GaN cladding layer 11 is grown, the temperature of the susceptor is lowered to about 800° C., and supply of all gases is stopped. Thereafter, SiH₄ is supplied only for a short period of time (e.g. 10 to 120 seconds), whereby Si adheres to the entire surface of the columnar semiconductor 30.

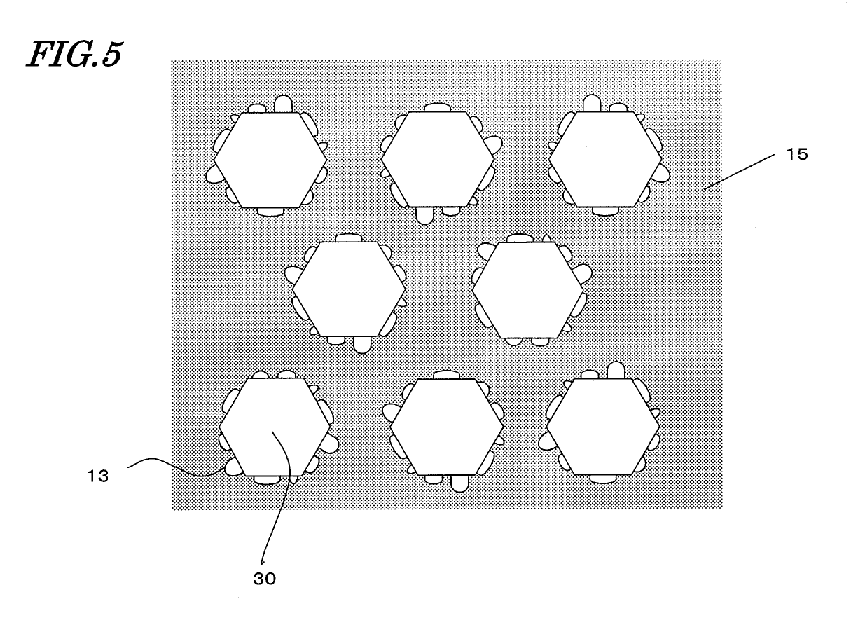

After supply of SiH₄ is stopped, TMA and NH₃ are supplied at adjusted flow rates, whereby AlN dots are formed on the side faces of each columnar semiconductor 30, in such a manner that the Si present on the surface of the columnar semiconductor 30 serves as nuclei. These AlN dots grow into the protrusions 13. Note that the upper end (apex) of each columnar semiconductor 30 is a narrow region with a size of about several dozen nm and several hundred nm, and therefore dots are unlikely to be formed in this region. Moreover, by rotating the susceptor during the growth of the protrusions 13, as shown in FIG. 4, it is possible to allow the AlN protrusions 13 to grow in substantially similar manners on each side face of the columnar semiconductor 30. After formation of the AlN protrusions 13, the temperature of the susceptor is elevated to about 900 to 1000° C., and supply of TMG is restarted at a usual growth temperature. At the same time, supply of Cp₂Mg is greatly increased than the supply amount during the growth of the p-GaN cladding layer 11, and the p-GaN contact layer 12 is deposited.

Thereafter, as shown in FIG. 1 and FIG. 5, a resin containing phosphor (phosphor material 15) such as the Y₃Al₅O₁₂:Ce type is applied on the wafer, and the space between the columnar semiconductors 30 is filled with the phosphor material 15. In the case where the upper face of the phosphor material 15 after application is at a height exceeding the upper end of each columnar semiconductor 30, the phosphor material 15 is etched from the upper face to expose the p-GaN contact layer 12 of each columnar semiconductor 30.

Next, a metal film is deposited above the p-GaN contact layer 12, and subjected to patterning as necessary, thereby forming the p electrode 16. The columnar semiconductor 30 and the mask layer 8 in a predetermined region are etched, thus forming the n electrode 17 on the principal face of the GaN substrate 7.

Note that, the specific structure and material of the columnar semiconductors 30 is not limited to those described above. For example, the active layer may be composed of AlₐGa₁₋ₐN (0≦a<1) well layers and Al_{b}Ga_{1-b}N (0<a<b<1) barrier layers, and the n-cladding layer may be formed from n-Al_{c}Ga_{1-c}N (0<a<b<c<1) and the p-cladding layer from p-Al_{d}Ga_{1-d}N (0<a<b<d<1).

In the case where an active layer which combines AlₐGa₁₋ₐN (0≦a<1) well layers and Al_{b}Ga_{1-b}N (0<a<b<1) barrier layers is constructed, the emission wavelength becomes shorter than in the case where the active layer is composed of In_{W}Ga_{1-W}N (0<W<1) well layers and GaN barrier layers. When the emission wavelength becomes shorter, the proportion of light undergoing total reflection at the interface between the device and the outside increases, so that the light extraction efficiency is significantly degraded in a columnar semiconductor having no structures on its side faces. However, when the protrusions 13 are present on the side faces of the columnar semiconductor 30, degradation of light extraction efficiency can be reduced. Therefore, the present invention can be particularly useful when the emission wavelength is short.

### Embodiment 2

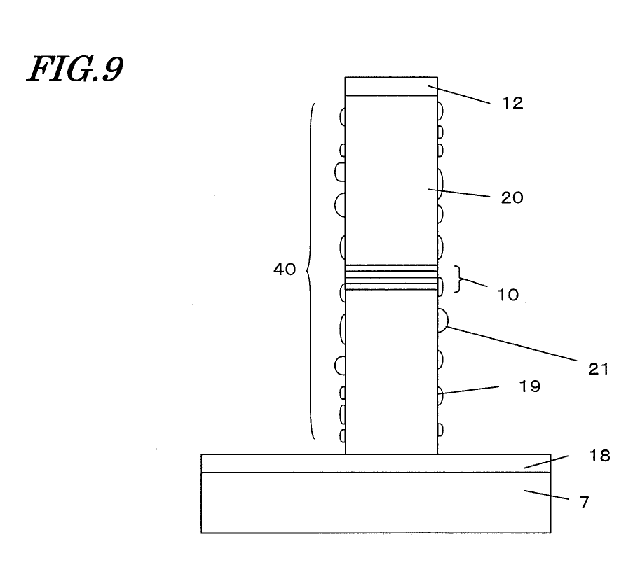

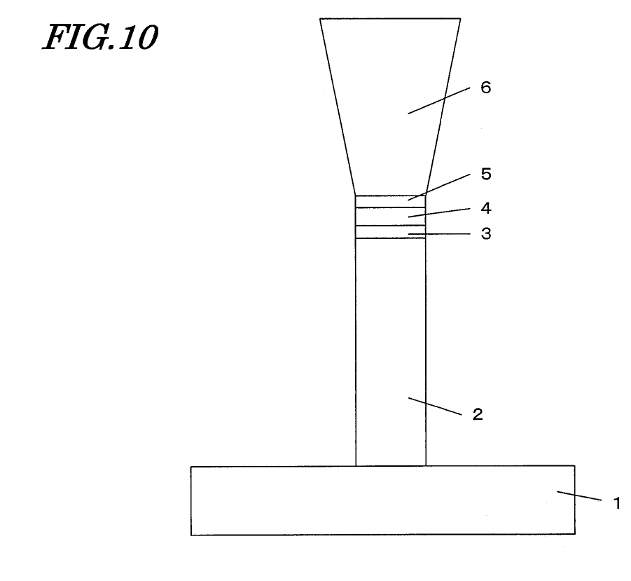

Hereinafter, with reference to FIG. 9, a second embodiment of the light-emitting device according to the present invention will be described. FIG. 9 schematically shows the construction of a vertical cross section of the light-emitting device of the present embodiment.

As shown in FIG. 9, the light-emitting device of the present embodiment includes a columnar semiconductor 40 supported on a GaN substrate 7 and a plurality of protrusions formed on side faces of the columnar semiconductor 40. Although FIG. 9 illustrates one columnar semiconductor 40, in actuality, a plurality of columnar semiconductors are grown on the GaN substrate 7.

The columnar semiconductor 40 has a columnar structure in which an n-Al_{Y}Ga_{1-Y}N (0≦Y≦1) cladding layer 19, an active layer 10, and a p-Al_{Z}Ga_{1-Z}N (0≦Z≦1) cladding layer 20 are stacked. The active layer 10 has a multi-quantum well structure in which In_{W}Ga_{1-W}N (0<W<1) well layers and GaN barrier layers are alternately deposited.

Such a columnar semiconductor 40 is also formed via crystal growth using MOVPE technique; however, it is formed via self-organization, instead of selective growth using a mask.

Hereinafter, a preferable embodiment of a method of forming the light-emitting device of the present embodiment will be described.

First, the GaN substrate 7 is provided, inserted into the reactor of an MOVPE apparatus, and subjected to cleaning at a high temperature. The substrate on which to grow the columnar semiconductors 40 does not need to be composed of GaN, but may be composed of Si, SiC, sapphire or the like.

Next, the susceptor is cooled to near 530° C., and an appropriate amount of each of TMG, trimethylaluminum (TMA), NH₃, and SiH₄ is supplied into the reactor, together with a hydrogen carrier gas, and thus the n-Al_{X}Ga_{1-X}N (0≦X≦1) buffer layer 18 is grown on the GaN substrate 7. At this time, the growth temperature of the n-Al_{X}Ga_{1-X}N buffer layer 18, the supply ratio of V/III groups, the Al mole fraction (X value), the film thickness, and the like are moderately controlled. In the present embodiment, these parameters may be adjusted as follows.

growth temperature: 300 to 650° C.

V/III group supply ratio: 3000 to 15000

Al mole fraction (X value): 0.03 to 0.1

film thickness: 1 to 1000 nm

Note that, if the growth temperature is less than 300° C., crystal growth in the n-Al_{X}Ga_{1-X}N buffer layer 18 does not occur, and if the growth temperature exceeds 650° C., the role of a buffer layer is not fulfilled. If the Al mole fraction is less than 0.03, the difference in lattice constant from the underlying GaN is so small that the intended effect cannot be obtained. On the other hand, if the Al mole fraction exceeds 0.1, the strain becomes too large for the Stransky-Krastanov growth mode to occur. The n-Al_{X}Ga_{1-X}N buffer layer 18 is able to form seeds to become the nuclei of columnar crystals even if the layer is only a few atoms thick. Therefore, depending on the other conditions, it may not be a problem if the n-Al_{X}Ga_{1-X}N buffer layer 18 has a thickness of about 1 nm. However, if this thickness becomes too large beyond 1000 nm, there is a possibility that local imbalances may occur in the dot distribution within the plane.

Thus, the growth conditions for the n-Al_{X}Ga_{1-X}N buffer layer 18 are important for ensuring that the semiconductor crystals to be grown thereupon are formed as nanoscale columnar structures. When the growth conditions are appropriately controlled, it becomes possible to allow dots functioning as growth nuclei of the columnar structures to be formed on the surface of the n-Al_{X}Ga_{1-X}N buffer layer 18.

The dots on the surface of the n-Al_{X}Ga_{1-X}N buffer layer 18 are formed due to a difference in lattice constant between the GaN substrate 7 and the n-Al_{X}Ga_{1-X}N buffer layer 18, and they occur in the Stransky-Krastanov growth mode. In other words, the dots to become nuclei of the columnar structures are ascribable to a strain field occurring on the surface of the n-Al_{X}Ga_{1-X}N buffer layer 18, and appear in a manner of self-formation at places where threading dislocations in the GaN substrate 7 locally lower in density. Therefore, there is a tendency that the growth nuclei are formed at a density which is substantially equal to the threading dislocation density (about 1.0×10⁶ to 1.0×10⁸ cm⁻²) of the GaN substrate 7. For this reason, even if no particular mask for selective growth is used, the density of columnar semiconductors (i.e., the number of them per unit area) grown on the GaN substrate 7 is about as large as the threading dislocation density in the GaN substrate.

Since the size and distribution of dots occurring on the surface of the n-Al_{X}Ga_{1-X}N buffer layer 18 can be controlled by adjusting the growth conditions for the n-Al_{X}Ga_{1-X}N buffer layer 18, this consequently makes it possible to control the cross-sectional size and density of the columnar semiconductors 40. Thus, a columnar semiconductor 40 which is grown in a manner of self-organization also has the shape of a generally hexagonal column, as in Embodiment 1.

Next, the temperature of the susceptor is elevated to about 900 to 1000° C., and the flow rates of the respective gases are adjusted, whereby the n-Al_{Y}Ga_{1-Y}N (0≦Y≦1) cladding layer 19 doped with an n-type impurity grow in columnar forms. After this, steps similar to the steps according to Embodiment 1 are performed, involving the growth up to the p-Al_{Z}Ga_{1-Z}(0≦Z≦1) N cladding layer 20, formation of the AlN protrusions 21, formation of the p-GaN contact layer 12, and application of a phosphor material and formation of electrodes.

According to the present embodiment, the columnar semiconductors 40 and the AlN protrusions 21 are formed in a manner of self-organization, and therefore lithography steps and etching steps are not needed. Moreover, since the columnar semiconductors 40 are minute structures on the nanoscale, as compared to semiconductor layers which are provided in laminar forms on a substrate, the threading dislocation density is reduced and point defects are few.

Moreover, via the AlN protrusions 21, light which is generated in the active layer 10 is efficiently taken outside from the side faces of the columnar semiconductors 40. Therefore, absorption of the emitted light by the GaN substrate 7 is also suppressed. As a result, the light extraction efficiency is improved over conventional light-emitting devices.

As has been described above, what is significant in the light-emitting device of the present invention is that, by forming a multitude of protrusions on the side faces of a columnar semiconductor, it is possible to suppress reflection of emitted light at interfaces between the light-emitting device and the outside and improve the light extraction efficiency, without performing cumbersome steps such as processing of the light-emitting surface and peeling of the substrate.

Note that, the effect of filling the interspaces in the array of columnar semiconductors with a phosphor material to enhance the mechanical strength of the light-emitting device can be sufficiently obtained also in the case where no protrusions are provided on the side faces of the columnar semiconductors.

### INDUSTRIAL APPLICABILITY

As compared to conventional thin-film type light-emitting devices, a light-emitting device according to the present invention has superior emission characteristics and an improved light extraction efficiency. A light-emitting device according to the present invention can be used as a light source which emits light from green to ultraviolet, and is also applicable in white LED applications.

1. A light-emitting device comprising:
at least one columnar semiconductor having a light-emitting portion composed of a nitride compound semiconductor;
a plurality of protrusions formed on a side face of the columnar semiconductor; and
a p electrode and an n electrode for supplying a current to the light-emitting portion,
wherein,
each of the plurality of protrusions is composed of a material having a larger band gap than a band gap of the nitride semiconductor in the light-emitting portion.

2. (canceled)

3. The light-emitting device of claim 1, wherein each of the plurality of protrusions has a size of no less than 5 nm and no more than 500 nm along a direction perpendicular to an axial direction of the columnar semiconductor.

4. The light-emitting device of claim 3, wherein the columnar semiconductor has a multilayer structure including an n-cladding layer, a p-cladding layer, and an active layer provided between the n-cladding layer and the p-cladding layer, the active layer functioning as the light-emitting portion.

5. The light-emitting device of claim 1, comprising a plurality of said columnar semiconductors, and a substrate supporting the plurality of columnar semiconductors.

6. The light-emitting device of claim 5, wherein the substrate is composed of a nitride compound semiconductor.

7. The light-emitting device of claim 5, wherein a phosphor material is provided in between the plurality of columnar semiconductors.

8. The light-emitting device of claim 7, wherein the phosphor material absorbs at least a portion of light which is emitted from the columnar semiconductor, contains a phosphor which emits light having a longer wavelength than a wavelength of the light, and is filled in between the columnar semiconductors.

9. The light-emitting device of claim 8, wherein one of the p electrode and the n electrode covers the plurality of columnar semiconductors and the phosphor material.

10. The light-emitting device of claim 5, comprising: at least one first conductive layer connected to the p electrodes of the plurality of columnar semiconductors; and at least one second conductive layer connected to the n electrodes of the plurality of columnar semiconductors.

11. The light-emitting device of claim 10, wherein the first conductive layer and the second conductive layer serve also as, respectively, a plurality of p electrodes and a plurality of n electrodes.

12. The light-emitting device of claim 11, wherein the phosphor material is located between a plane which is defined by the first conductive layer and a plane which is defined by the second conductive layer.

13. The light-emitting device of claim 1, wherein each of the plurality of columnar semiconductors has a length of no less than 1×10² nm and no more than 1×10⁵ nm along an axial direction.

14. A light-emitting device comprising:
a substrate;
a plurality of columnar semiconductors arranged on the substrate, each having a light-emitting portion composed of a nitride compound semiconductor;
a plurality of protrusions formed on a side face of each columnar semiconductor;
a phosphor material being filled in between the plurality of columnar semiconductors and being in contact with the columnar semiconductors;
a first electrode layer covering the phosphor material and the plurality of columnar semiconductors and being electrically connected to one end of each columnar semiconductor; and
a second electrode layer being electrically connected to another end of each columnar semiconductor.

15. An illumination device comprising:
the light-emitting device of claim 1; and
a circuit for controlling emission of light by the light-emitting device.
